(19) United States
(12) Patent Application Publication
(10) Pub. No.: US 2026/0342073 A1
(43) Pub. Date: Oct. 29, 2026

(54) E-FUSE

(71) Applicant: Infineon Technologies Austria AG, Villach (AT)

(72) Inventors: Alessandro FERRARA, Villach (AT); Aliaksandr SUBOTSKI, Villach (AT); Clemens MATTERSDORFER, Villach (AT); Ching Tiu HSU, Villach (AT); Filip HORMOT, Villach (AT); Prashanth Sudarshan PILLAMARI, Villach (AT); Michael KROPFITSCH, Köttmannsdorf (AT); Edmund Sales CABATBAT, München (DE)

(21) Appl. No.: 19/188,321

(22) Filed: Apr. 24, 2025

(51) Int. Cl. H02H 3/06; G01R 19/25; G01R 19/32; H02H 3/08

(52) U.S. Cl. CPC H02H 3/06; G01R 19/25; G01R 19/32; H02H 3/08

(57) ABSTRACT

According to some embodiments, an e-fuse comprises a switch, an analog current sensing branch configured to generate a first sensed load current for the switch, a digital current sensing branch configured to generate a second sensed load current for the switch, a hand-over detector configured to select between the first sensed load current or the second sensed load current to generate a load monitor current for the switch based on an operating mode of the switch, and a controller configured to control the switch based on the load monitor current.

### TECHNICAL FIELD

The present disclosure relates to the field of protection circuits.

### BACKGROUND

Overcurrent protection may be provided to a device by using a fuse, such as an analog fuse. An e-fuse is an electronic device that monitors the load current and interrupts the current if an overcurrent threshold is exceeded. The e-fuse is not destroyed in response to overcurrent as with an analog fuse.

### SUMMARY

This Summary is provided to introduce a selection of concepts in a simplified form that are further described below in the Detailed Description. This Summary is not intended to identify key factors or essential features of the claimed subject matter, nor is it intended to be used to limit the scope of the claimed subject matter.

According to some embodiments, an e-fuse comprises a switch, an analog current sensing branch configured to generate a first sensed load current for the switch, a digital current sensing branch configured to generate a second sensed load current for the switch, a hand-over detector configured to select between the first sensed load current or the second sensed load current to generate a load monitor current for the switch based on an operating mode of the switch, and a controller configured to control the switch based on the load monitor current.

According to some embodiments, an e-fuse package comprises a switch die comprising a switch, a controller die comprising an analog current sensing branch configured to generate a first sensed load current for the switch, a digital current sensing branch configured to generate a second sensed load current for the switch, a hand-over detector configured to select between the first sensed load current or the second sensed load current to generate a load monitor current for the switch based on an operating mode of the switch, and a controller configured to control the switch based on the load monitor current, interconnects between the switch die and the controller die, and a mold compound encapsulating the switch die, the controller die, and the interconnects.

According to some embodiments, a method comprises generating a first sensed load current for an e-fuse switch in an analog current sensing branch, generating a second sensed load current for the e-fuse switch in a digital current sensing branch, selecting between the first sensed load current or the second sensed load current to generate a load monitor current for the e-fuse switch based on an operating mode of the e-fuse switch, and controlling the e-fuse switch based on the load monitor current.

According to some embodiments, a system comprises means for generating a first sensed load current for an e-fuse switch in an analog current sensing branch, means for generating a second sensed load current for the e-fuse switch in a digital current sensing branch, means for selecting between the first sensed load current or the second sensed load current to generate a load monitor current for the e-fuse switch based on an operating mode of the e-fuse switch, and means for controlling the e-fuse switch based on the load monitor current.

To the accomplishment of the foregoing and related ends, the following description and annexed drawings set forth certain illustrative aspects and implementations. These are indicative of but a few of the various ways in which one or more aspects may be employed. Other aspects, advantages, and novel features of the disclosure will become apparent from the following detailed description when considered in conjunction with the annexed drawings.

### DESCRIPTION OF THE DRAWINGS

FIG. 1 is a diagram illustrating an e-fuse, in accordance with some embodiments.

FIG. 2 is a diagram illustrating an e-fuse, in accordance with some embodiments.

FIG. 3 is a diagram illustrating an e-fuse device package, in accordance with some embodiments.

FIG. 4 is a diagram illustrating current sensor selection based on drain-to source voltage, in accordance with some embodiments.

FIG. 5 is a diagram illustrating current sensor selection based on drain current, in accordance with some embodiments.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices are shown in block diagram form in order to facilitate describing the claimed subject matter.

It is to be understood that the following description of embodiments is not to be taken in a limiting sense. The scope of the present disclosure is not intended to be limited by the embodiments described hereinafter or by the drawings, which are taken to be illustrative only. The drawings are to be regarded as being schematic representations and elements illustrated in the drawings are not necessarily shown to scale. Rather, the various elements are represented such that their function and general purpose become apparent to a person skilled in the art.

All numerical values within the detailed description and the claims herein are modified by "about" or "approximately" the indicated value, and take into account experimental error and variations that would be expected by a person having ordinary skill in the art.

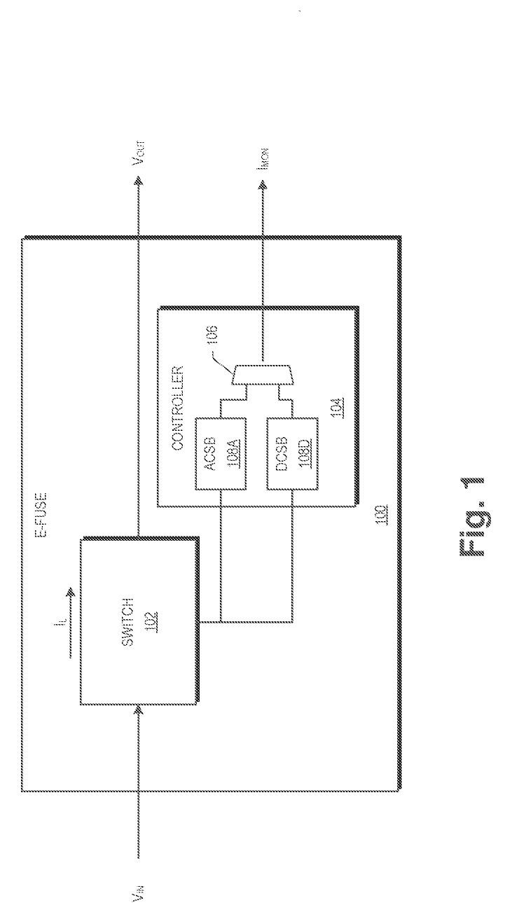

Referring to FIG. 1 a diagram of an e-fuse 100 is provided, in accordance with some embodiments. The e-fuse 100 comprises a switch 102 and a controller 104 that measures fuse current (I_{L}) passing through the switch 102 to generate a load monitor current (I_{MON}). The fuse current (I_{L}) passing through the switch 102 may be provided to a load. A supervisory controller (not shown) associated with the load may use the current monitor signal (I_{MON}) for controlling the load. In some embodiments, controller 104 opens the switch 102 if the load monitor current (I_{MON}) exceeds a trip threshold.

In some embodiments, the switch 102 is a power field effect transistor (FET). The controller 104 provides current sensing for all phases of operation of the switch 102, such as a start-up state (e.g., charging a capacitive load), a full-load state (high current at steady state), or a light load state (low current at stead-state). During steady-state operation, a hand-over detector 106 in the controller 104 enables an analog current sensing branch (ACSB) 108A to provide high accuracy. However, during light load operation, the hand-over detector 106 enables a digital current sensing branch (DCSB) 108D to avoid leakage effects inherent in the analog current sensing branch 108A, especially at high temperature. In addition, during the start-up state, the controller 104 enables the digital current sensing branch 108D to obviate the need for a power consuming charge pump or negative power supply to power the analog current sensing branch 108A before the output voltage (V_{OUT}) of the e-fuse 100 rises and approaches the input voltage (V_{IN}).

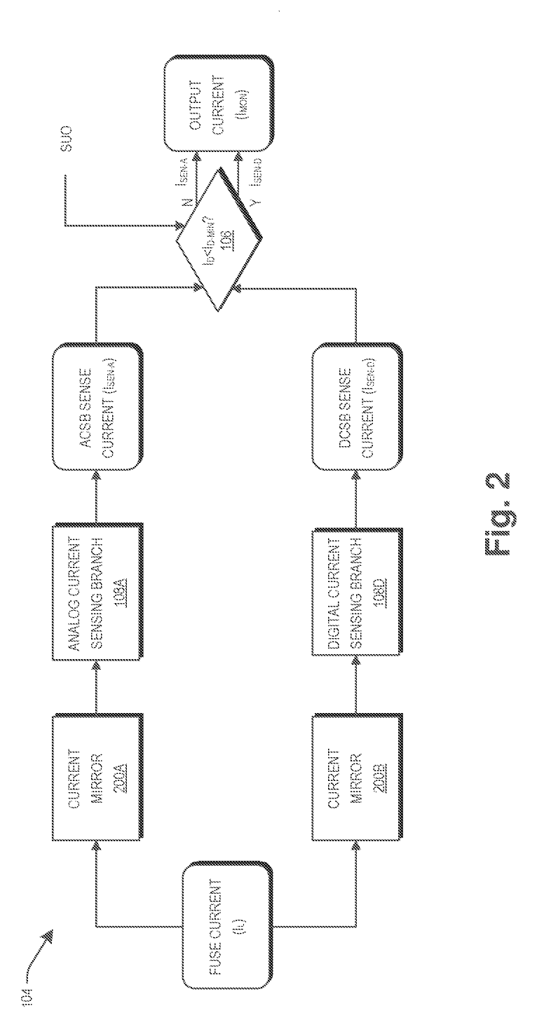

FIG. 2 is a simplified block diagram of the e-fuse 100, in accordance with some embodiments. In FIG. 2, blocks with rounded corners represent signals, while rectangular blocks represent circuitry. The fuse current (I_{L}) is provided to a first current mirror 200A for generating a scaled fuse current for the analog current sensing branch 108A and to a second current mirror 200B for generating a scaled fuse current for the digital current sensing branch 108D. In some embodiments, the current mirrors 200A, 200B have different scaling factors. If the same scaling factor is used, one of the current mirrors 200A, 200B may be omitted. The analog current sensing branch 108A generates a sensed load current (I_{SEN-A}) and the digital current sensing branch 108D generates a sensed load current (I_{SEN-D}). The hand-over detector 106 determines if the drain current (I_{D}) flowing through the switch 102 is less than a predetermined threshold (I_{D-MIN}), representing a low load condition. If I_{D} < I_{D-MIN}, the hand-over detector 106 selects I_{SEN-D} as the signal used to generate the load monitor current (I_{MON}). If I_{D} ≥ I_{D-MIN}, the hand-over detector 108 selects I_{SEN-A} as the signal used to generate the load monitor current (I_{MON}). In some embodiments, the hand-over detector 106 receives a start-up override signal (SUO) that forces the selection of I_{SEN-D} to generate I_{MON} during a start-up state. In some embodiments, the drain current (I_{D}) used by the hand-over detector 106 is generated based on the output of one of the current mirrors 200A, 200B. The predetermined threshold (I_{D-MIN}) would depend on the scaling factor of the current mirror 200A, 200B.

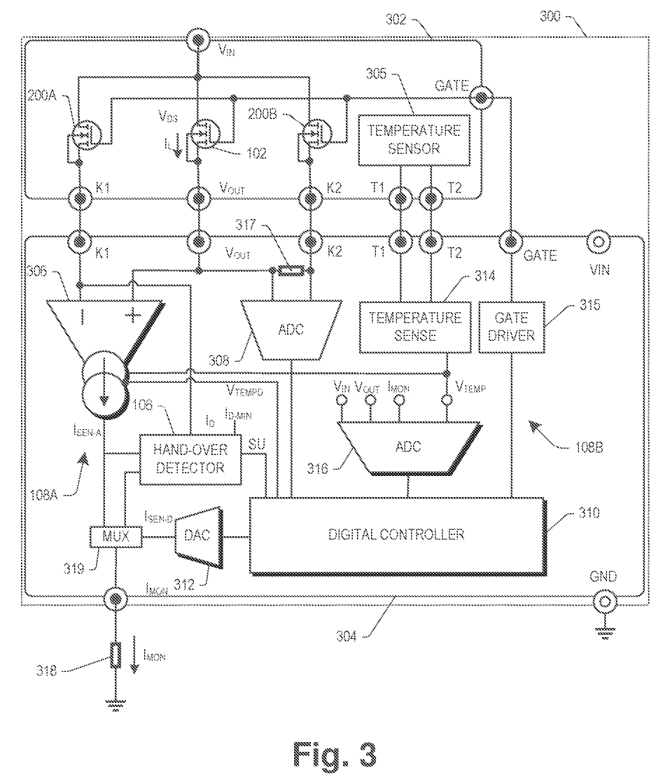

FIG. 3 is a diagram of an e-fuse device package 300, in accordance with some embodiments. In some embodiments, the e-fuse device package 300 comprises a co-packaged switch die 302 and a controller die 304. Interconnects provided by a lead frame or wire bonding may interconnect the switch die 302 and the controller die 304. A mold compound may be provided to encapsulate the switch die 302, the controller die 304, and the interconnects to provide the e-fuse device package 300. In some embodiments, the switch die 302 comprises the switch 102, the current mirrors 200A, 200B, and a temperature sensor 305. In some embodiments, the controller die 304 comprises the analog current sensing branch 108A, the digital current sensing branch 108D, the hand-over detector 106.

In some embodiments, the analog current sensing branch 108A comprises a current-sense amplifier 306 referenced by an output of the switch 102 and amplifies the output of the current mirror 200A to generate the sensed load current (I_{SEN-A}). The analog current sensing branch 108A provides high accuracy under medium to high load currents and does not require temperature compensation.

In some embodiments, the digital current sensing branch 108D comprises an analog-to-digital converter (ADC) 308 connected to the switch 102 and the current mirror 200B, a digital controller 310, a digital-to-analog converter (DAC) 312, and a temperature sense unit 314 that reads the output of the temperature sensor 305 (e.g., a temperature-sensitive voltage or current) to generate a temperature signal (V_{TEMP}). In some embodiments, an ADC 316 receives various signals associated with the e-fuse 100, such as V_{IN}, V_{OUT}, I_{MON}, and V_{TEMP} is connected to the digital controller 310 to provide information for controlling the e-fuse 100.

In some embodiments, a current sense resistor 317 generates a voltage proportional to the current generated by the current mirror 200B (i.e., a scaled version of load current (I_{L}). The voltage is provided to the ADC 308 and processed by the digital controller 310 to generate digital sensed load current. The digital controller 310 sends the digital sensed load current to the DAC 312, and the DAC generates an analog signal to provide the sensed load current (I_{SEND-D}). Although the current sense resistor 317 is illustrated as being part of the controller die 304, the current sense resistor 317 may be provided in the, in the e-fuse device package 300 external to the switch die 302 and the controller die 304, external to the e-fuse device package 300 on a printed circuit board to which the e-fuse device package 300 is mounted, or omitted entirely. If the current sense resistor 317 is omitted the ADC 308 receives current inputs that may be processed by the digital controller 31-.

The output generated by the current sense resistor 317 representing the load current (I_{L}) may be affected by temperature. In some embodiments, the digital controller 310 performs temperature compensation based on the temperature (V_{TEMP}) read by the temperature sensor 305 and received by the temperature sense unit 314. In some embodiments, the digital controller 310 performs a linear compensation for the digital current sensing branch 108D using a digital gain factor that depends on the analog output temperature (V_{TEMP}) generated by the temperature sense unit 314 and converted to a digital signal by the ADC 316 to the voltage generated by the current sense resistor 317. The digital controller 310 may compensate the current measurement by the analog current sensing branch 108A by applying a digital compensation signal (V_{TEMPD}) as a bias to the current-sense amplifier 306 or by applying the analog output temperature (V_{TEMP}) from the temperature sense unit 314 as a bias to the current-sense amplifier 306. Although both the analog and digital offset applied to the current-sense amplifier 306 are illustrated in FIG. 3, only one is needed.

In some embodiments, the temperature sensor 305 comprises a metal resistor integrated on an interlayer dielectric over a silicon layer in which the switch 102 and the current mirrors 200A, 200B are formed. The metal resistor is electrically insulated from, but thermally coupled to the switch 102. The temperature sense unit 314 may read a voltage across the metal resistor to generate V_{TEMP}. In some embodiments, the temperature sensor 305 comprises a silicon diode integrated into a bulk region of the silicon in which the switch 102 is formed, where the cathode of the diode is electrically connected to the drain of the switch 102. The temperature sense unit 314 may read a current generated by the silicon diode to generate V_{TEMP}.

In some embodiments, the digital controller 310 uses the inputs provided by the ADC 316 for controlling the e-fuse 100. The drain-to-source voltage (V_{DS}) of the switch may be determined by subtracting V_{OUT} from V_{IN}. The drain-to-source voltage (V_{DS}) may be used to determine if the e-fuse 100 is in the start-up state. The digital controller 310 enables a gate driver 315 to provide gate signals to the switch 102 and the current mirrors 200A, 200B. If the load monitor current (I_{MON}) exceeds a trip threshold, the digital controller 310 removes the gate signal to trip the e-fuse 100.

The hand-over detector 106 receives the sensed load current (I_{SEND-A}) from the analog current sensing branch 108A and the sensed load current (I_{SEND-D}) from the digital current sensing branch 108D and selects which signal to provide as the load monitor current (I_{MON}) by configuring a multiplexer 319. A current sense resistor 318 may be provided to generate a voltage proportional to the load monitor current (I_{MON}).

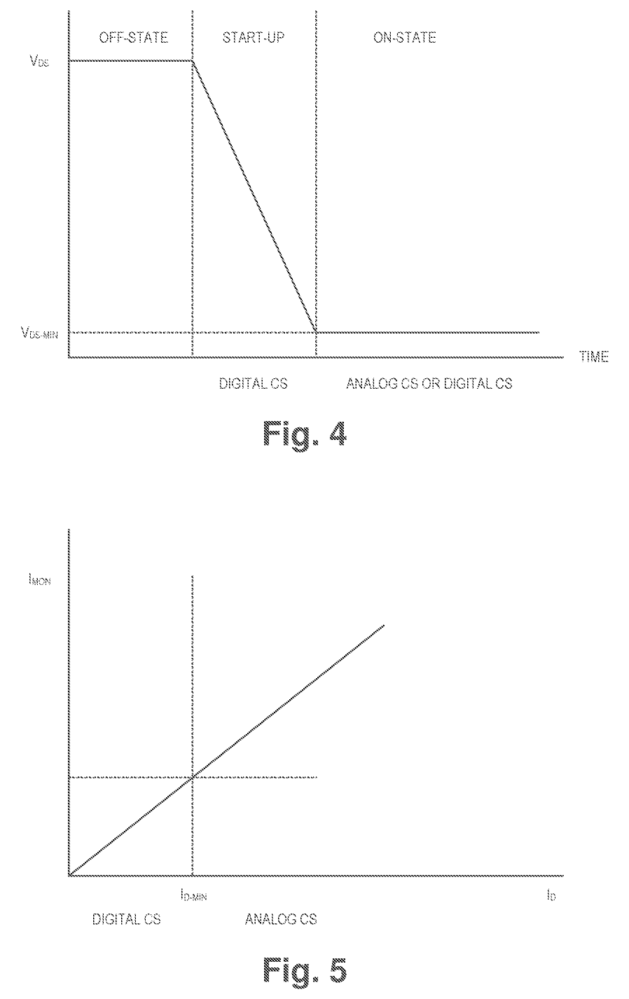

FIG. 4 is a diagram illustrating current sensor selection based on drain-to-source voltage, in accordance with some embodiments. During the start-up state, the hand-over detector 106 receives the start-up override signal (SUO) from the digital controller 310 to select the sensed load current (I_{SEND-D}) from the digital current sensing branch 108D as the load monitor current (I_{MON}). The digital controller 310 asserts the start-up override signal (SUO) responsive to V_{DS} being greater than a threshold, V_{DS-MIN}.

FIG. 5 is a diagram illustrating current sensor selection based on drain current, in accordance with some embodiments. During steady-state operation (e.g., the on state in FIG. 4), the digital controller 310 de-asserts the start-up override signal (SUO), and the hand-over detector 106 controls the multiplexer 319 based on the drain current (I_{D}) of the switch 102 (representative of the load current). In some embodiments, the scaled version of the drain current (I_{D}) generated by one of the current mirrors 200A, 200B is used as a representation of the drain current (I_{D}). If the drain current (I_{D}) is less than the predetermined threshold (I_{D-MIN}), representing a low load state, the hand-over detector 106 selects I_{SEN-D} from the digital current sensing branch 108D as the signal used to generate the load monitor current (I_{MON}). If I_{D} ≥ I_{D-MIN}, representing a high load state, the hand-over detector 106 selects I_{SEN-A} from the analog current sensing branch 108A as the signal used to generate the load monitor current (I_{MON}).

Selecting between the digital current sensing branch 108D and the analog current sensing branch 108A to generate the load monitor current (I_{MON}) based on the operating mode of the e-fuse 100 allows the most accurate sensing branch 108D, 108A. Using the digital current sensing branch 108D during the start-up state obviates the need for a current consuming charge pump or negative power supply for the current-sense amplifier 306 in the analog current sensing branch 108A. For a light load state, the digital current sensing branch 108D is selected to avoid the error cause by the offset voltage on the current-sense amplifier 306 in the analog current sensing branch 108A. For a high load state (i.e., any current greater than the low load state), the analog current sensing branch 108A is selected to provide the highest accuracy.

According to some embodiments, an e-fuse comprises a switch, an analog current sensing branch configured to generate a first sensed load current for the switch, a digital current sensing branch configured to generate a second sensed load current for the switch, a hand-over detector configured to select between the first sensed load current or the second sensed load current to generate a load monitor current for the switch based on an operating mode of the switch, and a controller configured to control the switch based on the load monitor current.

According to some embodiments, the analog current sensing branch comprises a current mirror configured to generate a scaled signal representing load current through the switch and a current sense amplifier connected to the current mirror to receive the scaled signal and connected to the switch and configured to generate the first sensed load current as a function of the scaled signal.

According to some embodiments, the digital current sensing branch comprises a current mirror configured to generate a scaled signal representing load current through the switch; an analog-to-digital converter connected to the current mirror to receive the scaled signal and connected to the switch, and a digital-to-analog converter, wherein the controller is connected to the analog-to-digital converter and configured to generate a digital sensed load current based on the scaled signal and the digital-to-analog converter is configured to generate the second sensed load current based on the digital sensed load current.

According to some embodiments, the digital current sensing branch comprises a current sense resistor connected to the current mirror and the analog-to-digital converter and the controller is configured to generate the digital sensed load current based on a voltage drop across the current sense resistor resulting from the scaled signal.

According to some embodiments, the e-fuse comprises a temperature sensor configured to determine a temperature of the switch, wherein the controller is configured to compensate at least one of the digital sensed load current or the first sensed load current based on the temperature.

According to some embodiments, the e-fuse comprises an analog-to-digital converter connected to the controller and configured to receive an input voltage of the switch and an output voltage of the switch, wherein the controller is configured to determine a voltage across the switch based on the input voltage and the output voltage and generate a start-up override signal based on the voltage across the switch, and the hand-over detector is configured to select the second sensed load current to generate the load monitor current for the switch responsive to the start-up override signal.

According to some embodiments, the hand-over detector is configured to receive a load current signal and determine the operating mode based on the load current signal.

According to some embodiments, the hand-over detector is configured to responsive to the operating mode being a low current state based on the load current signal being less than a predetermined threshold, select the second sensed load current to generate the load monitor current and responsive to the operating mode being a high current state based on the load current signal being greater than the predetermined threshold, select the first sensed load current to generate the load monitor current.

According to some embodiments, an e-fuse package comprises a switch die comprising a switch, a controller die comprising an analog current sensing branch configured to generate a first sensed load current for the switch, a digital current sensing branch configured to generate a second sensed load current for the switch, a hand-over detector configured to select between the first sensed load current or the second sensed load current to generate a load monitor current for the switch based on an operating mode of the switch, and a controller configured to control the switch based on the load monitor current, interconnects between the switch die and the controller die, and a mold compound encapsulating the switch die, the controller die, and the interconnects.

According to some embodiments, the switch die comprises a first current mirror connected to the analog current sensing branch and configured to generate a first scaled signal representing load current through the switch and a second current mirror connected to the digital current sensing branch and configured to generate a second scaled signal representing load current through the switch.

According to some embodiments, the analog current sensing branch comprises a current mirror configured to generate a scaled signal representing load current through the switch and a current sense amplifier connected to the current mirror to receive the scaled signal and connected to the switch and configured to generate the first sensed load current as a function of the scaled signal.

According to some embodiments, the digital current sensing branch comprises a current mirror configured to generate a scaled signal representing load current through the switch, an analog-to-digital converter connected to the current mirror to receive the scaled signal and connected to the switch, and a digital-to-analog converter, wherein the controller is connected to the analog-to-digital converter and configured to generate a digital sensed load current based on the scaled signal and the digital-to-analog converter is configured to generate the second sensed load current based on the digital sensed load current.

According to some embodiments, the digital current sensing branch comprises a current sense resistor connected to the current mirror and the analog-to-digital converter and the controller is configured to generate the digital sensed load current based on a voltage drop across the current sense resistor resulting from the scaled signal.

According to some embodiments, the switch die comprises a temperature sensor configured to determine a temperature of the switch, wherein the controller is configured to compensate at least one of the digital sensed load current or the first sensed load current based on the temperature.

According to some embodiments, the controller die comprises an analog-to-digital converter connected to the controller and configured to receive an input voltage of the switch and an output voltage of the switch, wherein the controller is configured to determine a voltage across the switch based on the input voltage and the output voltage and generate a start-up override signal based on the voltage across the switch, and the hand-over detector is configured to select the second sensed load current to generate the load monitor current for the switch responsive to the start-up override signal.

According to some embodiments, the hand-over detector is configured to receive a load current signal and determine the operating mode based on the load current signal.

According to some embodiments, the hand-over detector is configured to responsive to the operating mode being a low current state based on the load current signal being less than a predetermined threshold, select the second sensed load current to generate the load monitor current and responsive to the operating mode being a high current state based on the load current signal being greater than the predetermined threshold, select the first sensed load current to generate the load monitor current.

According to some embodiments, a method comprises generating a first sensed load current for an e-fuse switch in an analog current sensing branch, generating a second sensed load current for the e-fuse switch in a digital current sensing branch, selecting between the first sensed load current or the second sensed load current to generate a load monitor current for the e-fuse switch based on an operating mode of the e-fuse switch, and controlling the e-fuse switch based on the load monitor current.

According to some embodiments, the method comprises determining a voltage across the e-fuse switch, generating a start-up override signal based on the voltage across the e-fuse switch, and selecting the second sensed load current to generate the load monitor current for the e-fuse switch responsive to the start-up override signal.

According to some embodiments, the method comprises receiving a load current signal, determining the operating mode based on the load current signal, responsive to the operating mode being a low current state based on the load current signal being less than a predetermined threshold, selecting the second sensed load current to generate the load monitor current, and responsive to the operating mode being a high current state based on the load current signal being greater than the predetermined threshold, selecting the first sensed load current to generate the load monitor current.

Various operations of embodiments are provided herein. In one embodiment, one or more of the operations described may constitute computer readable instructions stored on one or more computer readable media, which if executed by a computing device, will cause the computing device to perform the operations described. The order in which some or all of the operations are described should not be construed as to imply that these operations are necessarily order dependent. Alternative ordering will be appreciated by one skilled in the art having the benefit of this description. Further, it will be understood that not all operations are necessarily present in each embodiment provided herein.

Any aspect or design described herein as an "example" is not necessarily to be construed as advantageous over other aspects or designs. Rather, use of the word “example” is intended to present one possible aspect and/or implementation that may pertain to the techniques presented herein. Such examples are not necessary for such techniques or intended to be limiting. Various embodiments of such techniques may include such an example, alone or in combination with other features, and/or may vary and/or omit the illustrated example.

As used in this application, the term "or" is intended to mean an inclusive "or" rather than an exclusive "or". That is, unless specified otherwise, or clear from context, "X employs A or B" is intended to mean any of the natural inclusive permutations. That is, if X employs A; X employs B; or X employs both A and B, then "X employs A or B" is satisfied under any of the foregoing instances. In addition, the articles "a" and "an" as used in this application and the appended claims may generally be construed to mean "one or more" unless specified otherwise or clear from context to be directed to a singular form. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated example implementations of the disclosure. In addition, while a particular feature of the disclosure may have been disclosed with respect to only one of several implementations, such feature may be combined with one or more other features of the other implementations as may be desired and advantageous for any given or particular application. Furthermore, to the extent that the terms "includes", "having", "has", "with", or variants thereof are used in either the detailed description or the claims, such terms are intended to be inclusive in a manner similar to the term "comprising."

What is claimed is:

1. An e-fuse, comprising:
a switch;
an analog current sensing branch configured to generate a first sensed load current for the switch;
a digital current sensing branch configured to generate a second sensed load current for the switch;
a hand-over detector configured to select between the first sensed load current or the second sensed load current to generate a load monitor current for the switch based on an operating mode of the switch; and
a controller configured to control the switch based on the load monitor current.

2. The e-fuse of claim 1, wherein:
the analog current sensing branch comprises:
a current mirror configured to generate a scaled signal representing load current through the switch; and
a current sense amplifier connected to the current mirror to receive the scaled signal and connected to the switch and configured to generate the first sensed load current as a function of the scaled signal.

3. The e-fuse of claim 1, wherein:
the digital current sensing branch comprises:
a current mirror configured to generate a scaled signal representing load current through the switch;
an analog-to-digital converter connected to the current mirror to receive the scaled signal and connected to the switch; and
a digital-to-analog converter, wherein:
the controller is connected to the analog-to-digital converter and configured to generate a digital sensed load current based on the scaled signal; and
the digital-to-analog converter is configured to generate the second sensed load current based on the digital sensed load current.

4. The e-fuse of claim 3, wherein:
the digital current sensing branch comprises:
a current sense resistor connected to the current mirror and the analog-to-digital converter; and
the controller is configured to generate the digital sensed load current based on a voltage drop across the current sense resistor resulting from the scaled signal.

5. The e-fuse of claim 3, comprising:
a temperature sensor configured to determine a temperature of the switch, wherein:
the controller is configured to compensate at least one of the digital sensed load current or the first sensed load current based on the temperature.

6. The e-fuse of claim 1, comprising:
an analog-to-digital converter connected to the controller and configured to receive an input voltage of the switch and an output voltage of the switch, wherein:
the controller is configured to:
determine a voltage across the switch based on the input voltage and the output voltage; and
generate a start-up override signal based on the voltage across the switch; and
the hand-over detector is configured to:
select the second sensed load current to generate the load monitor current for the switch responsive to the start-up override signal.

7. The e-fuse of claim 1, wherein:
the hand-over detector is configured to:
receive a load current signal; and
determine the operating mode based on the load current signal.

8. The e-fuse of claim 7, wherein:
the hand-over detector is configured to:
responsive to the operating mode being a low current state based on the load current signal being less than a predetermined threshold, select the second sensed load current to generate the load monitor current; and
responsive to the operating mode being a high current state based on the load current signal being greater than the predetermined threshold, select the first sensed load current to generate the load monitor current.

9. An e-fuse package, comprising:
a switch die comprising a switch;
a controller die comprising:
an analog current sensing branch configured to generate a first sensed load current for the switch;
a digital current sensing branch configured to generate a second sensed load current for the switch;
a hand-over detector configured to select between the first sensed load current or the second sensed load current to generate a load monitor current for the switch based on an operating mode of the switch; and
a controller configured to control the switch based on the load monitor current;
interconnects between the switch die and the controller die; and
a mold compound encapsulating the switch die, the controller die, and the interconnects.

10. The e-fuse package of claim 9, wherein:
the switch die comprises:
a first current mirror connected to the analog current sensing branch and configured to generate a first scaled signal representing load current through the switch; and
a second current mirror connected to the digital current sensing branch and configured to generate a second scaled signal representing load current through the switch.

11. The e-fuse package of claim 9, wherein:
the analog current sensing branch comprises:
a current mirror configured to generate a scaled signal representing load current through the switch; and
a current sense amplifier connected to the current mirror to receive the scaled signal and connected to the switch and configured to generate the first sensed load current as a function of the scaled signal.

12. The e-fuse package of claim 9, wherein:
the digital current sensing branch comprises:
a current mirror configured to generate a scaled signal representing load current through the switch;
an analog-to-digital converter connected to the current mirror to receive the scaled signal and connected to the switch; and
a digital-to-analog converter, wherein:
the controller is connected to the analog-to-digital converter and configured to generate a digital sensed load current based on the scaled signal; and
the digital-to-analog converter is configured to generate the second sensed load current based on the digital sensed load current.

13. The e-fuse package of claim 12, wherein:
the digital current sensing branch comprises:
a current sense resistor connected to the current mirror and the analog-to-digital converter; and
the controller is configured to generate the digital sensed load current based on a voltage drop across the current sense resistor resulting from the scaled signal.

14. The e-fuse package of claim 12, wherein:
the switch die comprises:
a temperature sensor configured to determine a temperature of the switch, wherein:
the controller is configured to compensate at least one of the digital sensed load current or the first sensed load current based on the temperature.

15. The e-fuse package of claim 9, wherein:
the controller die comprises:
an analog-to-digital converter connected to the controller and configured to receive an input voltage of the switch and an output voltage of the switch, wherein:
the controller is configured to:
determine a voltage across the switch based on the input voltage and the output voltage; and
generate a start-up override signal based on the voltage across the switch; and
the hand-over detector is configured to:
select the second sensed load current to generate the load monitor current for the switch responsive to the start-up override signal.

16. The e-fuse package of claim 9, wherein:
the hand-over detector is configured to:
receive a load current signal; and
determine the operating mode based on the load current signal.

17. The e-fuse package of claim 16, wherein:
the hand-over detector is configured to:
responsive to the operating mode being a low current state based on the load current signal being less than a predetermined threshold, select the second sensed load current to generate the load monitor current; and
responsive to the operating mode being a high current state based on the load current signal being greater than the predetermined threshold, select the first sensed load current to generate the load monitor current.

18. A method, comprising:
generating a first sensed load current for an e-fuse switch in an analog current sensing branch;
generating a second sensed load current for the e-fuse switch in a digital current sensing branch;
selecting between the first sensed load current or the second sensed load current to generate a load monitor current for the e-fuse switch based on an operating mode of the e-fuse switch; and
controlling the e-fuse switch based on the load monitor current.

19. The method of claim 18, comprising:
determining a voltage across the e-fuse switch;
generating a start-up override signal based on the voltage across the e-fuse switch; and
selecting the second sensed load current to generate the load monitor current for the e-fuse switch responsive to the start-up override signal.

20. The method of claim 18, comprising:
receiving a load current signal;
determining the operating mode based on the load current signal;
responsive to the operating mode being a low current state based on the load current signal being less than a predetermined threshold, selecting the second sensed load current to generate the load monitor current; and
responsive to the operating mode being a high current state based on the load current signal being greater than the predetermined threshold, selecting the first sensed load current to generate the load monitor current.
